(19) United States
(12) Patent Application Publication
(10) Pub. No.: US 2006/0137601 A1
(43) Pub. Date: Jun. 29, 2006

(54) Method of synthesis of 3d silicon colloidal photonic crystals by micromolding in inverse silica opal (miso)

(76) Inventors: Hernan Miguez, Valencia (ES); Geoffrey Alan Ozin, Toronto (CA); San Ming Yang, Toronto (CA); Nicolas Tetreault, Toronto (CA)

Correspondence Address: Ralph A. Dowell of DOWELL & DOWELL P.C., 2111 Eisenhower Ave, Suite 406, Alexandria, VA, 22314, US

(21) Appl. No.: 10/535,946

(22) PCT Filed: Jan. 9, 2004
(86) PCT No.: PCT/CA04/00032

§ 371 Date: Aug. 31, 2005

Related U.S. Application Data
(60) Provisional application No. 60/438,994, filed on Jan. 10, 2003.

(51) Int. Cl. C30B 15/00; G02B 5/30

(52) U.S. Cl. 117/35; 264/1.31

(57) ABSTRACT

A new type of synthetic silicon colloidal photonic colloidal crystal is described presenting a different topology than previously synthesised high refractive index contrast colloidal photonic crystals. It has been built using a new synthesis process based upon micromolding in inverse silica opals (MISO), where the micromold has a structure of interconnected air cavities in a silica matrix. By chemical vapour deposition of disilane within this micromold, a continuous and uniform silicon layer of controlled thickness is formed, which coats the walls of the silica matrix. Later, by dissolution of the starting silica micromold it is possible to obtain a face centered cubic silicon colloidal photonic crystal with a topology never observed before and which presents a full photonic band gap, as indicated by theoretical photonic band structure calculations making them useful as optical components of envisioned all-optical microphotonic crystal devices, circuits, chips and computers.

### FIELD OF THE INVENTION

The present invention relates to a new process of synthesizing 3D colloidal photonic crystals by filling an oxide mold produced by coating a colloidal crystal with oxide, removing the oxide and infiltrating a material.

### BACKGROUND OF THE INVENTION

The fabrication of photonic crystals based on colloidal crystal templating represents one of the most attractive approaches among those currently being considered to overcome the challenge of building up a 3D. periodic modulation of refractive index at the micrometer length scale. So far, important advances have been made by using micrometer size silica or latex sphere colloidal crystals, i.e. artificial opals, as templates. Briefly, opal molds are built from a suspension of colloidal particles either by sedimentation on a flat substrate, which gives rise to large size face centred cubic (fcc) crystals, or by convection force induced self-assembly, which results in planarized fcc crystals of controlled thickness. By infiltrating the interstitial sites of these structures with high refractive index materials, such as silicon, germanium or titanium oxide, and later removal of the colloidal crystal scaffold, an inverted opal structure consisting of interconnected air cavities in a high dielectric constant medium is attained. This chemical approach to the fabrication of photonic crystals leads to optical quality materials with the suitable geometry, topology and dielectric contrast as to allow the opening of photonic band gaps.

In this same context, it has also been demonstrated that it is possible to synthesize a new type of colloidal crystal made of a wide variety of dense and porous oxides, and metals by means of a template approach that utilizes a mold that consists of a periodic distribution of interconnected spherical cavities in a latex background, which is obtained by replicating a silica colloidal crystal in latex and subsequently dissolving the silica template. Infiltration of different precursors is used to coat the internal surfaces of the latex mold with different materials and gives rise to a novel kind of hybrid inverse colloidal crystal. (S. M. Yang, N. Coombs, G. A. Ozin, Adv. Mater. 2000, 12, 1940; P. Jiang, J. F. Bertone, V. L. Colvin, Science 2001, 291, 453.) The method has been referred to as micromolding in inverse polymer opals (MIPO) and while the approach is quite versatile it cannot be easily applied to obtain compositions whose synthesis requires high temperatures or corrosive precursors.

Therefore it would be very advantageous to provide a method of micromolding which can be applied to obtain compositions whose synthesis requires high temperatures or corrosive precursors.

### SUMMARY OF THE INVENTION

It is an object of the present invention to describe a new synthetic strategy for making high dielectric contrast 3D colloidal photonic crystals based on a colloidal crystal templating approach named micromolding in inverse silica opal (MISO). This method enables 3D colloidal photonic crystals to be obtained that present a new topology.

When silicon is used, theoretical photonic band structure calculations modeling the so-built structure show that a full photonic band gap is achieved with distinctive features relative to inverted colloidal photonic crystals. This method represents an alternative way to fabricate photonic band gap materials based on colloidal crystal templating. There are numerous applications where these new 3D (particularly using silicon) colloidal photonic crystal lattices may be integrated with optical waveguides and fibers to make optically functional microphotonic crystal devices and optical circuits.

The invention described herein is useful in the emerging field of production of three-dimensional photonic crystals with complete photonic band gaps at optical telecommunication wavelengths. Specifically this invention relates to high refractive index contrast 3D silicon photonic crystals and more particularly a new way of synthesizing a 3D silicon colloidal photonic crystal with a new topology that is distinct to previously synthesised 3D silicon inverse colloidal photonic crystals. The new preparation involves silicon micromolding in inverse silica opals (MISO), that is, templating silicon by use of a micromold with a structure based on interconnected air cavities in a silica matrix. Silicon infiltration within this lattice provides a continuous and uniform layer of silicon with a controlled thickness deposited over the walls of the silica micromold. Sacrificial etching or removal of the silica of the micromold generates a face centered cubic silicon colloidal photonic crystal with a novel topology, which as indicated by theoretical photonic band structure calculations displays a full photonic band gap at optical telecommunication wavelengths and therefore portends utility as new miniaturized optical components for all-optical devices, circuits, chips and computers.

In the invention disclosed herein a new type of 3D colloidal photonic crystal is described that presents a different topology than previously synthesized high refractive index contrast 3D colloidal photonic crystals (A. Blanco, E. Chomski, S. Grabtchak, M. Ibisate, S. John, S. W. Leonard, C. Lopez, F. Meseguer, H. Miguez, J. P. Mondia, G. A. Ozin, O. Toader, H. M. van Driel, Nature 2000, 405, 437). The colloidal photonic crystal synthesized using the method disclosed herein have been made using a new process based on micromolding in inverse silica opals (MISO), where the micromold has a structure based upon interconnected air cavities in a silica matrix.

The procedure to create an inverted silica opal from a latex template has been previously described in the scientific literature (B. T. Holland, C. F. Blanford, T. Do, A. Stein, Chem. Mater. 1999; 11, 795). In a preferred embodiment of the process, using chemical vapour deposition (CVD) of disilane within this micromold it is possible to form a continuous and uniform silicon layer of controlled thickness, which coats the walls of the silica micromold. Later, by dissolution of the starting micromold it is possible to obtain face centered cubic silicon colloidal photonic crystals with a topology never observed before and which present a full photonic band gap, as indicated by theoretical photonic band structure calculations, at optical telecommunication wavelengths.

In one aspect of the invention there is provided a process for making an inverted crystal from a colloidal crystal, comprising the steps of:

a) producing a colloidal crystal using colloidal particles of pre-selected size, shape and composition, the colloidal crystal having interstitial void spaces between the colloidal particles;

b) infiltrating a pre-selected amount of a precursor of an oxide into the interstitial void spaces in the colloidal crystal under conditions which produce a coating of oxide on an outer surface of the colloidal particles;

c) removing the colloidal particles of pre-selected composition leaving behind an oxide mold;

d) infiltrating a precursor of a material of pre-selected refractive index into an interior of the oxide mould and depositing the material of pre-selected refractive index on an inner surface of the oxide mould; and

e) removing the oxide mould to give an inverted crystal made of the material of pre-selected refractive index.

In this aspect of the invention the oxide may be silica.

In another aspect of the invention there is provided a process for producing a 3D photonic colloidal crystal, comprising:

a) producing a colloidal crystal having a pre-selected crystal structure, the colloidal crystal being formed of colloidal particles made from a pre-selected material each having an outer surface which define a void interstitial lattice;

b) infiltrating an oxide precursor into the void interstitial lattice for coating exposed outer surfaces of each colloidal particle until a pre-determined volume fraction of the void interstitial lattice is filled under conditions effective to grow an oxide layer on the exposed outer surfaces from the oxide precursor to form a connected network of oxide coated colloidal particles;

c) removing the colloidal crystal particle material and leaving behind an oxide skeletal network defining connected cavities;

d) growing layer-by-layer a material having a pre-selected dielectric constant on an inner surface of the connected network of oxide cavities to a pre-selected thickness; and

e) removing the oxide skeletal network to give a photonic crystal having a structure of shells of the material interconnected by cylindrical channels in air background.

In another aspect of the invention there is provided a 3D photonic colloidal crystal product grown by a process, comprising:

a) producing a colloidal crystal having a pre-selected crystal structure, the colloidal crystal being formed of colloidal particles made from a pre-selected material each having an outer surface which define a void interstitial lattice;

b) infiltrating a silica precursor into the void interstitial lattice for coating exposed outer surfaces of each colloidal particle until a pre-determined volume fraction of the void interstitial lattice is filled under conditions effective to grow a silica layer on the exposed outer surfaces from the silica precursor to form a connected network of silica coated colloidal particles;

c) removing the colloidal crystal particle material and leaving behind a silica mold including a silica skeletal network defining connected cavities;

d) growing layer by layer a material having a pre-selected dielectric constant on an inner surface of said connected network of silica cavities to a pre-selected thickness; and

e) removing said silica skeletal network to give a structure of shells of said material interconnected by cylindrical channels in air background.

### BRIEF DESCRIPTION OF THE DRAWINGS

The method of synthesizing 3D silicon colloidal photonic crystals with a novel topology using micromolding in inverse silica opal (MISO) according to the present invention will now be described, by way of example only, reference being made to the accompanying drawings, in which:

FIG. 1 is a diagram showing the different steps involved in the MISO process. (i) Initially softened latex colloidal crystal showing the interpenetration of the spheres; (ii) Infiltration of the silica within the void interstitial lattice of the latex colloidal crystal; (iii) Dissolution or burning of the latex; (iv) Layer-by-layer growth of silicon on the inner surface of the silica cavities. by CVD; (v) Dissolution of the silica gives rise to the structure of spherical silicon shells interconnected by cylindrical channels in air background. Depending on the degree of infiltration achieved in step (ii), two different silicon networks can be attained, represented in paths A and B. All samples presented in this work are made following path A.

FIG. 2 are scanning electron micrographs (SEM) showing cleaved edges of the different structures build up during the MISO process: (a) inverted silica colloidal crystal; (b) silicon-silica composite after infiltration by CVD of disilane; (c) and (d) different crystalline faces of the final periodically arranged interconnected silicon shells after removal of the silica mold.

FIG. 3 shows high magnification SEM micrographs showing the different connectivity of the silicon shells achieved using (a) an inverted silica colloidal crystal and (b) a silica colloidal crystal.

FIG. 4 is a model of (111) planes of silicon infiltrated (a) inverted silica and (b) direct silica colloidal crystals. The maximum silicon layer thickness is indicated with a vertical bar in the right panels. The different materials are drawn in different colours: silicon (dark grey), silica (light grey), and air (white).

FIG. 5 shows the evolution of the full photonic band gap to midgap ratio as a function of the shell inner radius R_{Si}. The inset shows the model of the structure employed for the calculations.

FIG. 6(a) shows photonic band structure for a lattice of silicon spherical shells connected by hollow silicon cylindrical channels (R_{Si}/L=0.352), the full gap is shaded along the different directions of the first Brillouin zone plotted, (b) shows the normalized reflectance spectra for a silicon photonic colloidal crystal built using MISO.

### DETAILED DESCRIPTION OF INVENTION

The present invention broadly provides a process for making an inverted crystal from a colloidal crystal based on a colloidal crystal templating approach named micromolding in inverse silica opal (MISO).In preferred embodiments of the invention there is provided a new strategy for synthesizing a 3D silicon colloidal photonic crystal with a novel topology that is distinct to the known structure class of 3D silicon inverse colloidal photonic crystals. This new class of 3D silicon colloidal photonic crystal exhibits a complete photonic band gap in the optical telecommunication wavelength range, around 1.5 microns.

The method for producing 3D colloidal photonic crystals according to the present invention is as follows. First, a colloidal crystal is produced and may be produced using any known technique using particles of pre-selected size, shape and composition. The colloidal crystal will have a network of interstitial void spaces between the colloidal particles. For example, colloidal crystals can be built from a suspension of microspheres either by sedimentation on a flat substrate, which gives rise to large size face centred cubic (fcc) crystals, or by convection force induced self-assembly of microspheres on a flat substrate, which results in planarized fcc crystals of controlled thickness, or by infiltration and later crystallization of microspheres in surface relief patterns, which results in confined fcc crystals of controlled thickness and orientation. Details of some of the methods employed in the work described herein may be found in copending U.S. patent application Ser. No. 09/977,254 filed Oct. 16, 2001, which is incorporated herein by reference in its entirety.

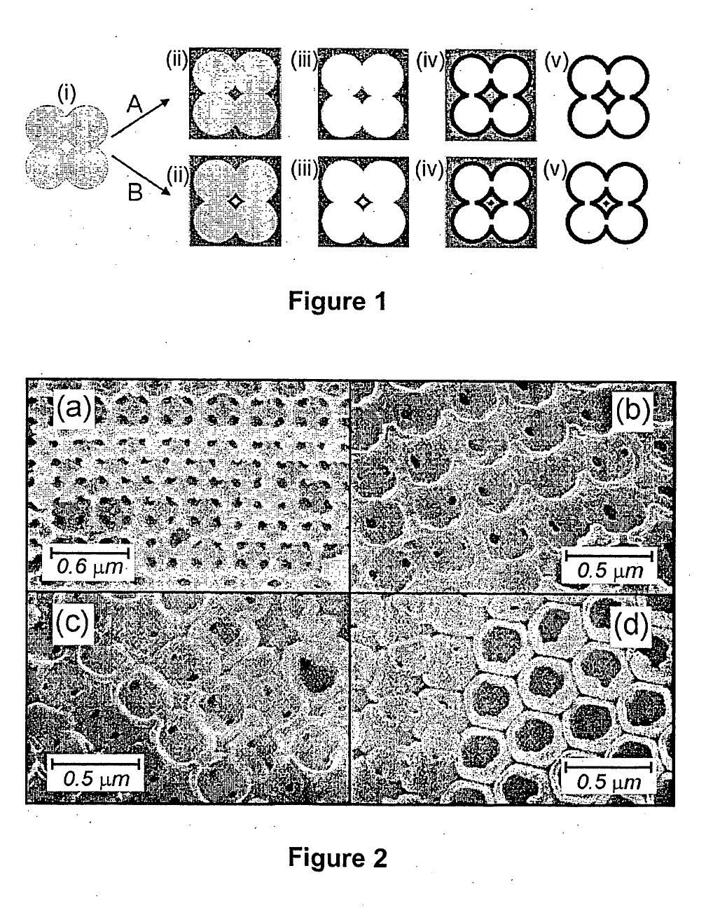

For the present invention, a preferred colloidal particle may be latex microspheres. Once the desired colloidal crystal is produced using latex particles, the silica micromold is created by silica deposition on the latex colloidal crystal, using a sol-gel precursor, for example, but not limited to (EtO)4Si as sol-gel precursor, which, through a hydrolytic polycondensation process, gives rise to the silica lattice. Latex microsphere diameters chosen for this non-limiting example were 350 nm in diameter, with a polydispersity lower than 2%. However it will be appreciated that the present invention is applicable to latex microspheres of any diameter. The latex template is subsequently removed either by calcination in air (preferably at about 580° C.) or by dissolution in an organic solvents such as, but not limited to, toluene, to leave behind an inverse silica colloidal crystal, the silica micromold. Two different kinds of inverted silica opal molds can be attained depending on the degree of infiltration of silica in the original latex template, as schematized in FIG. 1. On the one hand, complete infiltration (Type A in FIG. 1) gives rise to a single network of quasi-spherical voids in the structure after removal of the organic matrix. On the other, partial infiltration (Type B in FIG. 1) results in two independent, isolated networks, one corresponding to the not totally filled interstitial sites of the initial latex template and the other to the interconnected quasi-spherical cavities.

For production of inverted silicon photonic crystals exhibiting photonic bandgaps, the latex microspheres are substantially monodisperse having a diameter selected to give the cavities with diameters in the silica mold in a range from about 0.6 to about 3 microns.

For the MISO studies disclosed herein, the inventors employed silica inverted opals of the first type, hence avoiding the formation of a double silicon network. Silicon was then infiltrated in the silica micromold by static chemical vapor deposition (CVD) of disilane (Si₂H₆) (but it will be appreciated by those skilled in the art that other fluid sources of silane may be used). Disilane gas pressure of around 700 Torr was achieved in the sample cell and it was decomposed to amorphous silicon, as confirmed by Raman spectroscopy measurements, at temperatures between 200° C. and 400° C. High pressures, low temperatures and long decomposition times lead to homogeneous infiltration of silicon into the macroporous silica structure. A uniform silicon layer grows on the inside walls of the spherical cavities throughout the silica mold, its thickness being controlled by the deposition conditions and limited by the size of the circular windows interconnecting the large quasi-spherical cavities. Finally, the silica mold was removed by etching the sample in a 3 wt % aqueous HF solution. A diagram of the different structures built at each step of the MISO process is shown in the FIG. 1.

It will be understood that using chemical vapor deposition using silane is a preferred method but other methods may be used. For example, in addition to disilane, other precursors for silicon that could easily be infiltrated into silica colloidal crystals (opals) followed by sacrificial etching of the silica template include the following. Molecular beam and laser ablation of Si atoms followed by thermal post treatment in a controlled atmosphere to control the amorphous and crystalline silicon content. Capped and uncapped colloidal and molecular cluster forms of silicon using vapor, melt and solution-phase techniques followed by thermal post treatment. Infiltration of silane-based polymers using solution and melt impregnation and thermal post-treatment techniques. Other volatile CVD silane-based precursors may be taken from the homologous series SinH2n+2 where n=1,2,3 etc.

Examples of other silicon precursors, other deposition techniques, other forms of silicon for synthesizing the inverse silicon opal comprise, but are not limited by, the following. Capped silicon clusters like octasilacubanes (R₈Si₈) could be used as a Si source for CVD. Octa-tert-butyloctasilacubane vaporizes around 200□C and decomposes to silicon from 350-450□C. Furukawa K; Fujino M; Matsumoto N; Superlattice structure of octa-tert butylpentacyclo-[4.2.0.0(2,5).0(3,8).0(4,7)] octasilane found by reinvestigation of X-ray structure analysis, Journal Of Organometallic Chemistry 1996, Vol 515, Iss 1-2, pp 37-41. Yang C S; Bley R A; Kauzlarich S M; Lee H W H; Delgado G R; Synthesis of alkyl-terminated silicon nanoclusters by a solution route, Journal Of The American Chemical Society 1999, Vol 121, pp 5191-5195. Silicon nanocrystallites could be used to infiltrate the silica opal. Sweryda-Krawiec B; Cassagnneau T; Fendler J H; Ultrathin electroactive junctions assembled from silicon nanocrystallites and polypyrrole, Advanced Materials 1999, Vol 11, pp 644-659. Kanemitsu Y; Silicon and germanium nanoparticles, Light Emission in Silicon From Physics to Devices, Semiconductors and Semimetals, Academic Press, San Diego 1998, pp. 157-202. Brus L; Silicon polymers and nanocrystals,. Light Emission in Silicon From Physics to Devices, Semiconductors and Semimetals, Academic Press, San Diego 1998, pp 303-326. Abelson J R; Plasma deposition of hydrogenated amorphous silicon, studies of the growth surface, Applied Physics A, Materials Science & Processing 1993 Vol 56, pp 493-512. Yoon J H; Lim S H; Moon B Y; Jang J; Polycrystalline silicon film deposited at 300□C, Journal Of The Korean Physical Society 1999 Vol 35 S1017-S1020, Suppl. S. Bhat K N; Ramesh M C; Rao P R S; Ganesh B; Polysilicon technology, IETE Journal Of Research 1997 Vol 43, pp 143-154. Porous silicon could also be used, Cullis, A G; Canham L T; Calcott P D J; The structural and luminescence properties of porous silicon, Journal Of Applied Physics 1997 Vol 82, pp 909-965.

In addition, while silica is the preferred material from which the mold-is made, it will be understood that other materials could used, for example oxides could be used for the same purpose, such as TiO₂, GeO₂, etc . . . . They can be grown by a sol-gel method similar to the one used for growing the silica employed herein or by other techniques which will be familiar to those skilled in the art, a non-limiting example being chemical vapor deposition (CVD) of chlorides.

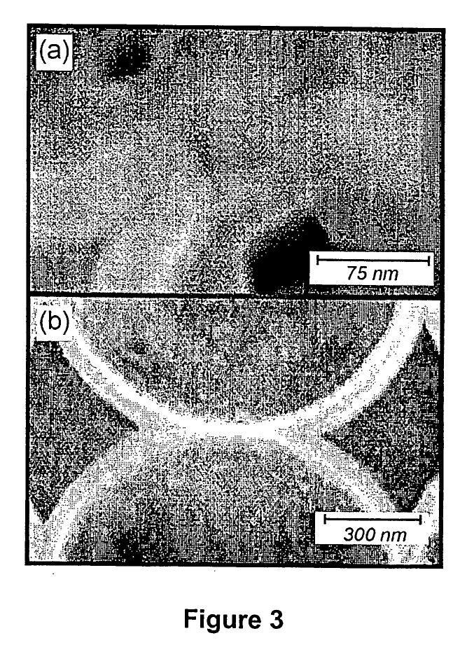

The steps of the MISO process performed were characterized using scanning electron microscopy (SEM). FIG. 2(a) shows a micrograph of a cleaved edge of the silica inverted opals employed as template molds. In the picture shown in FIG. 2(b), corresponding to a silica-silicon composite, it can be clearly seen that the inner silicon coating is very uniform and grows homogeneously in all cavities. The size of the windows interconnecting the cavities decreases as the growth on the walls of the channels takes place, finally leading to their occlusion and curtailing the process. FIGS. 2(c) and 2(d) show different crystalline faces of the final silicon-air structure. FIG. 3(a) explicitly shows the quasi-spherical silicon shells connected through quasi-cylindrical channels, which represent the main distinctive feature of these lattices. It can be seen that, although we replicate the face centered cubic (fcc) symmetry of the original latex opal template, the connectivity of the silicon backbone is different to that of inverted silicon opals. In the latter, the quasi-spherical air cavities are connected through circular windows resulting from the direct replica of the overlapping spheres of the original silica template. Therefore, we can conclude that MISO gives rise to a fcc photonic crystal with a new topology. For the sake of comparison, we show in FIG. 3(b) a detail of a cross section of an inverted silicon opal.

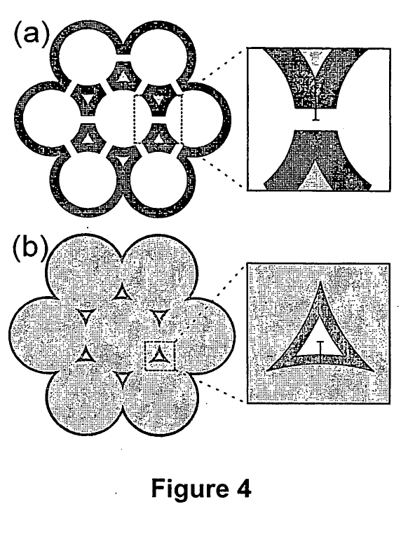

In any process in which the infiltration of the guest material takes place layer-by-layer and involves the mass transport of reactants or precursors through a void lattice, complete infiltration of the empty volume is not possible, the maximum coating thickness attainable being that which causes closure of the narrowest interconnecting windows. This imposes constraints to the tunability of the filling fraction and, consequently, of the photonic crystal properties of such lattices. According to this, it should be noticed that different restrictions regarding this maximum coating thickness apply for silicon grown within an opal (direct colloidal crystal) and within an inverted colloidal crystal, as in the MISO process. Diagrams of the cross sections of (111) planes of the two different lattices obtained by molding with direct and inverted silica colloidal crystals are presented in FIG. 4. In the former case, the maximum thickness will be determined by the size of the triangular openings between spheres in the (111) planes, which show the most dense arrangement of spheres among the fcc planes. The size of these openings will depend on the degree of interpenetration of the spheres, which can be controlled by thermal annealing. For example, for a cubic close packed lattice of non-overlapping spheres, the maximum coating thickness attainable is 0.07735·d, where d is the sphere diameter.

In the case of molding with an inverted opal, the circular windows interconnecting the air spherical cavities, such as those observed in the FIG. 1(a), allow the gas to flow through the whole void lattice of the inverted silica opal. As a consequence of the layer-by-layer growth of silicon, at some point these interconnecting windows will close, not allowing the gas to flow through the structure any longer. Therefore, the upper limit for the silicon layer thickness is the radius of these circular windows, which can be tuned by controlling thermally the degree of interpenetration of the spheres in the original latex colloidal crystal. It can be readily seen that a much wider range of thickness is achievable through MISO than using direct silica opals. As in the case of inverted silicon opals, below the upper limit, an accurate control of the final coating thickness can be attained by the cyclic repetition of the above-mentioned CVD procedure or by varying the pressure or temperature of the infiltration process. Therefore the silicon shell thickness available for each inverse silica opal micromold goes from 0 to the value at which the windows interconnecting the spherical cavities in the inverse silica opal micromold closes and this value depends on how interpenetrated the latex spheres were in the original latex colloidal crystal template.

In order to analyse the photonic crystal properties of these new structures, we performed photonic band structure calculations using a software program based on the plane wave expansion method. We modeled the lattice as spherical silicon shells interconnected by cylindrical hollow silicon tubes having the same thickness as the shells. A value for the refractive index of amorphous silicon of n=3.95 was used, after experimental results obtained for amorphous silicon thin films grown by CVD reported in the literature. An initial interpenetration of the air cavities of radius R in the inverted silica opal template (lattice constant L) was used such as R/L=0.3995 (for a structure of non overlapping cavities R/L=1/(2√2)=0.3535). The photonic band structure was calculated as the inner radius of the silicon coating R_{Si} from R_{Si}/L=0.3019 was varied, the limit imposed by the radius of the interconnecting windows, to 0.3995, which is the fixed outer radius of the shell. We find that a full photonic band gap, that is, a range of frequencies whose-propagation through the crystal is not allowed irrespective of the incident direction, opens up for a wide range of silicon shell thickness.

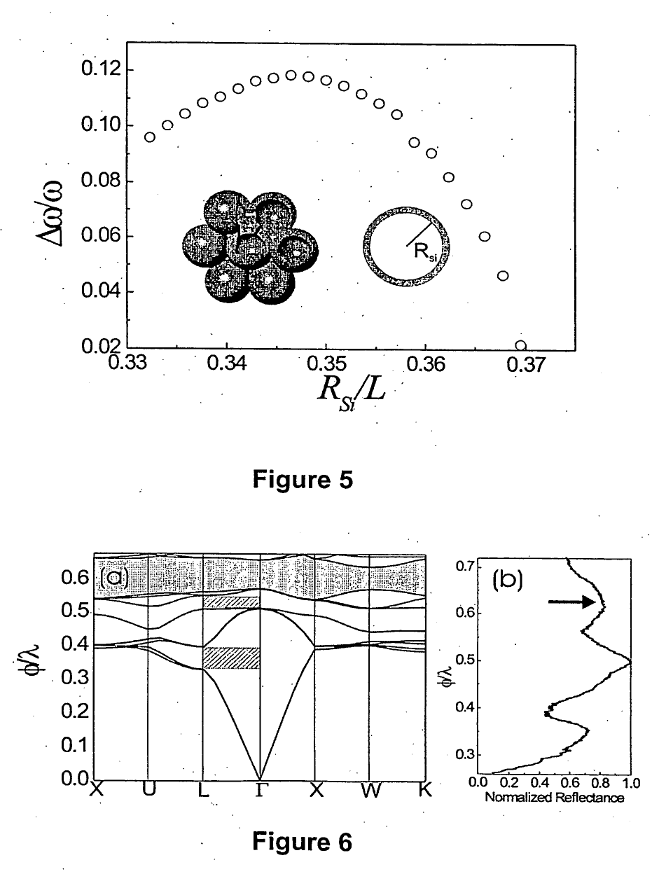

FIG. 5 shows the evolution of the full band gap to midgap ratio Δω/ω versus the inner radius of the silicon shell R_{Si} for the range 0.330<R_{Si}/L<0.375. The model employed in the calculations to simulate the structure is introduced as an inset. It should be noticed than among the silicon shell thickness for which the gap to midgap ratio is shown in FIG. 5, only those corresponding to Rsi/L>0.3475 could be grown by a layer by layer deposition of silicon onto a fcc structure of spheres. This represents a major difference and advantage of these new silicon photonic crystals with respect to silicon inverted opals, since the MISO method makes a wider range set of silicon filling fractions and interconnecting window sizes available. As the photonic band structure is very sensitive to variations of these two parameters, MISO technique increases the range of tunability of colloidal crystal based photonic crystals.

The optical properties of the final pure silicon photonic crystals were analysed by near infrared reflectance spectroscopy. The optical properties of the samples at each step of the fabrication process were studied by reflectance spectroscopy in the near infrared. Samples were illuminated with unpolarised light coming from a quartz lamp and through a microscope. A spatial filter was used so that the size of the spot tested was 40 μm×40 μm, smaller than the observed typical domain size. Light incident between 15° to 35° from normal incidence with respect to the (111) planes of the sample (Γ-L direction) was collected.

A Bomem Fourier transform infrared spectrometer, using a HgₓCd₍₁₋ₓ₎Te detector, was employed to perform the spectral analysis of the reflected light. Optical reflectance results for a crystal having a lattice constant L=1485 nm, a silicon shell thickness of 70 nm, and a radius of the window interconnecting spherical cavities of 205 nm are shown in FIG. 6 in units of φ/λ. The calculated photonic band structure which best fits the experimental data (R_{Si}/L=0.352) is also plotted along the main directions of the reciprocal lattice. The positions of the three reflectance maxima observed correspond fairly well to the three stop bands that opens up in the photonic band structure at the L point of the 1^{st} Brillouin zone and that are shaded in FIG. 6(a). Although the photonic band structure resembles that of the inverted silicon opal grown layer by layer, it must be noted that, in that case, such a silicon shell thickness is not compatible with a large interconnecting window size like the one of our new structure. In this sense, the new topology provides the possibility of building full photonic band gap materials having a very open network of channels, which might improve the functionality of these structures. The highest energy one matches the position at which the full band gap is expected after the calculations.

In conclusion, the inventors have disclosed herein a new synthetic route to high dielectric contrast 3D photonic crystals based on a colloidal crystal templating approach named micromolding in inverse silica opal (MISO). This method enables 3D silicon colloidal photonic crystals to be obtained that present a new topology and makes it possible to attain a much wider range of silicon shell thickness relative to inverted silicon colloidal photonic crystals. Theoretical photonic band structure calculations modelling the so-built structure show that a full photonic band gap is achieved with these distinctive features. This method represents an alternative way to fabricate photonic band gap materials based on colloidal crystal templating. While the present invention has been exemplified using silicon, it will be appreciated that other materials may be used having pre-selected dielectric constants selected to give a large enough dielectric contrast between air and the material so that the resulting inverted opal structure has a complete photonic bandgap. For example, germanium may be used as the dielectric material. Alternatively, silicon may be doped with various n-or p-type dopants. The colloidal photonic crystal lattice can have a structure such as face centered cubic, hexagonal close packed, a mixture of both or random packings of both.

The colloidal photonic crystal may be made of amorphous, nanocrystalline, polycrystalline or single crystal silicon. The colloidal photonic crystal may be made by micromolding in inverse silica opals where the diameter of the cavities in the micromold lies in the range from about 0.6 to about 3 microns.

The colloidal photonic crystal may be grown as a free standing planarized film by chemical or physical lift-off means from the substrate. Alternatively the colloidal photonic crystal may be grown as either a free standing microfiber or microcrystal by chemical or physical lift-off means from the substrate. A process of producing inverted crystals using the method disclosed herein in the form of elongate fibers may employ the method disclosed in United States copending national phase patent application from PCT Serial No. PCT/CA03/01949 which claims priority from U.S. Ser. No. 60/433,596, which is incorporated herein by reference in its entirety.

The inverse silica opal micromold may be made by silica deposition into a latex colloidal crystal template, the constituent microspheres of which had been necked by a predetermined amount using a controlled thermal annealing process thereby establishing the topology of the inverse silica opal micromold and consequently of the resulting colloidal photonic crystal. The process of necking used to control the degree of connectivity between microspheres may be accomplished using the method disclosed in United States copending patent application Ser. No. 10/255,578 which is incorporated herein by reference in its entirety.

As used herein, the terms “comprises”, “comprising”, “includes” and “including” are to be construed as being inclusive and open ended, and not exclusive. Specifically, when used in this specification including claims, the terms “comprises”, “comprising”, “includes” and “including” and variations thereof mean the specified features, steps or components are included. These terms are not to be interpreted to exclude the presence of other features, steps or components.

The foregoing description of the preferred embodiments of the invention has been presented to illustrate the principles of the invention and not to limit the invention to the particular embodiment illustrated. It is intended that the scope of the invention be defined by all of the embodiments encompassed within the following claims and their equivalents.

1. A process for making an inverted crystal from a colloidal crystal, comprising the steps of:
a) producing a colloidal crystal using colloidal particles of pre-selected size, shape and composition, the colloidal crystal having interstitial void spaces between the colloidal particles;
b) infiltrating a pre-selected amount of a precursor of an oxide into the interstitial void spaces in the colloidal crystal under conditions which produce a coating of oxide on an outer surface of the colloidal particles;
c) removing the colloidal particles of pre-selected composition leaving behind an oxide mold;
d) infiltrating a precursor of a material of pre-selected refractive index into an interior of the oxide mould and depositing the material of pre-selected refractive index on an inner surface of the oxide mould; and
e) removing the oxide mould to give an inverted crystal made of the material of pre-selected refractive index.

2. The method according to claim 1 wherein the oxide is silica, and wherein the colloidal particles of pre-selected size, shape and composition are latex microspheres.

3. The method according to claim 1 wherein the step of removing the colloidal particles of pre-selected composition leaving behind an oxide mold includes one of calcination in air at an effective temperature to remove the colloidal particles and removal by dissolution in an effective solvents to dissolve the colloidal particles.

4. The method according to claim 1 wherein the colloidal crystal lattice has a lattice structure which is one of face centered cubic, hexagonal close packed, a mixture of both and random packings of both.

5. The method according to claim 1 wherein the step of producing a colloidal crystal using colloidal particles of pre-selected size, shape and composition includes using controlled thermal annealing of the colloidal crystal give a predetermined amount of necking between the colloidal particles thereby establishing a desired colloidal crystal topology which is subsequently reflected in a topology of the inverted crystal.

6. The method according to claims 2 wherein the precursor of silica is a sol-gel precursor having a formula (EtO)₄Si.

7. The method according to claim 1 wherein the step of producing a colloidal crystal using colloidal particles of pre-selected size, shape and composition includes producing the colloidal crystal on a planar substrate so that the inverted colloidal photonic crystal is grown on a substrate as a planarized film.

8. The method according to claim 1 wherein the step of producing a colloidal crystal using colloidal particles of pre-selected size, shape and composition includes producing the colloidal crystal within geometrically and spatially defined surface relief patterns on a substrate so that the silicon inverted colloidal photonic crystal is grown within the geometrically and spatially defined surface relief patterns.

9. The method according to claim 8 wherein the geometrically and spatially defined surface relief patterns include microchannels and microwells in the surface of the substrate.

10. The method according to claim 1 wherein the step of producing a colloidal crystal using colloidal particles of pre-selected size, shape and composition includes producing the colloidal crystal on a surface of a planar substrate so that the inverted colloidal photonic crystal is grown on a substrate as a planarized film, including a step of lifting the planarized film off the surface of the substrate.

11. The method according to claim 10 wherein the step of lifting the planarized film off the surface of the substrate includes chemically or physically lifting the planarized film off the surface of the substrate.

12. The method according to claim 8 wherein the geometrically and spatially defined surface relief patterns include microchannels in the surface of the substrate, and including chemically or physically lifting the inverted crystal from the microchannels to give a free standing microfiber or microcrystal.

13. The method according to claim 1 wherein the material of pre-selected refractive index is selected from the group consisting of semiconductors and doped semiconductors.

14. The method according to claim 1 wherein the material of pre-selected refractive index is silicon.

15. The method according to claim 14 wherein the silicon making up the inverted crystal is one of amorphous, nanocrystalline, polycrystalline and single crystal silicon.

16. The method according to claim 14 wherein the precursor of silicon is a silicon containing gas.

17. The method according to claim 16 wherein the silicon containing gas is disilane (Si₂H₆), and wherein the step of depositing the silicon includes chemical vapor deposition (CVD) of disilane (Si₂H₆).

18. An inverted colloidal photonic crystal product produced according to the method of claim 1.

19. An inverted colloidal photonic crystal product produced according to the method of claim 14 wherein the inverted colloidal photonic crystal is a silicon inverted colloidal photonic crystal exhibiting a photonic band gap at optical telecommunication wavelengths.

20. The inverted colloidal photonic crystal product according to claim 19 wherein the photonic band gap is a complete photonic bandgap.

21. An inverted colloidal photonic crystal product produced according to the method of claim 1 wherein the material of pre-selected refractive index is selected to give a photonic crystal.

22. The inverted colloidal photonic crystal product according to claim 21 wherein the colloidal photonic crystal exhibits a photonic band gap.

23. The inverted colloidal photonic crystal product according to claim 22 wherein the photonic band gap is a complete photonic bandgap at pre-selected optical telecommunication wavelengths.

24. A process for producing a 3D photonic colloidal crystal, comprising:
a) producing a colloidal crystal having a pre-selected crystal structure, the colloidal crystal being formed of colloidal particles made from a pre-selected material each having an outer surface which define a void interstitial lattice;
b) infiltrating an oxide precursor into the void interstitial lattice for coating exposed outer surfaces of each colloidal particle until a pre-determined volume fraction of the void interstitial lattice is filled under conditions effective to grow an oxide layer on the exposed outer surfaces from the oxide precursor to form a connected network of oxide coated colloidal particles;
c) removing the colloidal crystal particle material and leaving behind an oxide skeletal network defining connected cavities;
d) growing layer-by-layer a material having a pre-selected dielectric constant on an inner surface of the connected network of oxide cavities to a pre-selected thickness; and
e) removing the oxide skeletal network to give a photonic crystal having a structure of shells of the material interconnected by cylindrical channels in air background.

25. The process according to claim 24 wherein the oxide is silica, and wherein the colloidal particles are substantially mono-disperse spherical particles so that the cavities are spherical cavities.

26. The process according to claim 24 wherein the pre-selected material is latex.

27. The process according to claim 25 wherein the silica precursor is a sol-gel precursor having a formula (EtO)₄Si.

28. The process according to claim 24 wherein the material having a pre-selected dielectric constant is silicon.

29. The process according to claim 24 wherein oxide skeletal network defines an inverted oxide opal structure.

30. The process according to claim 24 wherein the photonic crystal is a face centered cubic colloidal photonic crystal.

31. The process according to claim 29 the material having a pre-selected dielectric constant is silicon grown in a sufficient amount to give a silicon colloidal photonic crystal with a complete photonic bandgap.

32. The process according to claim 24 wherein said material having a pre-selected dielectric constant is selected to give a large enough dielectric contrast between air and said material so that said structure of shells of the material interconnected by cylindrical channels in air background has a complete photonic bandgap.

33. The process according to claim 24 wherein said material is silicon, and wherein said step of growing silicon includes infiltrating a silicon containing fluid into said connected network of oxide cavities for a pre-selected amount of time under effective conditions of temperature and pressure to give homogeneous infiltration and growth of silicon from said silicon containing fluid on the inner surface of said connected network of silica cavities.

34. The process according to claim 33 wherein the silicon containing fluid is disilane gas introduced into a reaction chamber containing the connected network of oxide cavities at a pressure of about 700 Torr at a temperature in a range from about 200° C. to about 400° C.

35. A 3D photonic colloidal crystal product grown by a process, comprising:
a) producing a colloidal crystal having a pre-selected crystal structure, the colloidal crystal being formed of colloidal particles made from a pre-selected material each having an outer surface which define a void interstitial lattice;
b) infiltrating a silica precursor into the void interstitial lattice for coating exposed outer surfaces of each colloidal particle until a pre-determined volume fraction of the void interstitial lattice is filled under conditions effective to grow a silica layer on the exposed outer surfaces from the silica precursor to form a connected network of silica coated colloidal particles;
c) removing the colloidal crystal particle material and leaving behind a silica mold including a silica skeletal network defining connected cavities;
d) growing layer by layer a material having a pre-selected dielectric constant on an inner surface of said connected network of silica cavities to a pre-selected thickness; and
e) removing said silica skeletal network to give a structure of shells of said material interconnected by cylindrical channels in air background.

36. The 3D photonic colloidal crystal product according to claim 35 wherein said colloidal particles are substantially mono-disperse spherical particles so that said cavities are spherical cavities.

37. The 3D photonic colloidal crystal product according to claim 35 wherein said pre-selected material is latex.

38. The 3D photonic colloidal crystal product according to claim 35 wherein said silica precursor is a sol-gel precursor having a formula (EtO)₄Si.

39. The 3D photonic colloidal crystal product according to claim 35 wherein said material is silicon.

40. The 3D photonic colloidal crystal product according to claim 35 wherein said silica skeletal network defines an inverted silica opal structure.

41. The 3D photonic colloidal crystal product according to claim 35 wherein said photonic crystal is a face centered cubic colloidal photonic crystal.

42. The 3D photonic colloidal crystal product according to claim 40 wherein said material is silicon grown in a sufficient amount to give a silicon colloidal photonic crystal with a complete photonic bandgap.

43. The 3D photonic colloidal crystal product according to claim 35 wherein the material having a pre-selected dielectric constant is selected to give a large enough dielectric contrast between air and said material so that the structure of shells of the material interconnected by cylindrical channels in air background has a complete photonic bandgap.

44. The 3D photonic colloidal crystal product according to claim 42 wherein the complete photonic band gap is around 1.5 microns.

45. The 3D photonic colloidal crystal product according to claim 25 wherein the monodisperse colloidal particles have a diameter selected to give the cavities with diameters in the silica mold in a range from about 0.6 to about 3 microns.

46. The method according to claim 25 wherein the latex microspheres are substantially monodisperse having a diameter selected to give the cavities with diameters in the silica mold in a range from about 0.6 to about 3 microns.

47. The method according to claim 1 wherein the precursor of the oxide is a sol-gel precursor.

48. The method according to claim 13 wherein the semiconductor is selected from the group consisting of silicon, germanium GaP, and InP.

49. The method according to claim 14 wherein the silicon is infiltrated into the oxide mold by one of chemical vapor deposition, plasma enhanced chemical vapor deposition, laser ablation of Si atoms or silicon clusters, molecular beam deposition of Si atoms or silicon clusters, infiltration of colloidal silicon, silicon nanoclusters or silane-based polymers using one of either vapor impregnation, solution impregnation and melt impregnation.
